(19) United States
(12) Patent Application Publication
(10) Pub. No.: US 2025/0102400 A1
(43) Pub. Date: Mar. 27, 2025

(54) METHOD FOR FILTERING A SIGNAL

(71) Applicant: SKF Magnetic Mechatronics, Saint-Marcel (FR)

(72) Inventors: Pierre BORNERT, Vernon (FR); Joël MOUTERDE, Blaru (FR); Joaquim DA SILVA, Sennely (FR)

(21) Appl. No.: 18/889,017

(22) Filed: Sep. 18, 2024

(30) Foreign Application Priority Data
Sep. 25, 2023 (FR) 2310163

(51) Int. Cl. G01M 13/028; G01H 17/00

(52) U.S. Cl. CPC G01M 13/028; G01H 17/00

(57) ABSTRACT

A method for filtering at least one signal to be filtered. The filtering being determined based on measurements representing the movement of a rotating shaft. The method includes defining at least one characterisation indicator of the rotating shaft. The characterisation indicator being obtained from a frequency analysis of the behaviour of the rotating shaft (step 120). The method includes determining a filtering template as a function of the characterisation indicator (step 130) and applying the filtering template to said signal to be filtered (step 140).

### CROSS-REFERENCE TO RELATED APPLICATION

This application claims priority to French Application No. 2310163, filed Sep. 25, 2023, the entirety of which is hereby incorporated by reference.

### FIELD

The present disclosure relates to the characterisation of a shaft rotating about an axis of rotation.

More specifically, the present disclosure relates to filtering a characterisation indicator of the gyroscopic effects and deformations of a rotating shaft in order to facilitate the control, modelling, monitoring, diagnosis and maintenance thereof.

### BACKGROUND

A perfectly balanced rotating system, such as a rotating shaft, rotates about an axis of rotation such that said axis of rotation is immobile relative to its theoretical position, and therefore relative to the environment close to the rotating shaft.

However, faults, deformations, gyroscopic effects or even effects due to the force of gravity can cause the axis of rotation to shift relative to its theoretical position during the rotation of said rotating shaft. This is the case, for example, for deformations of the rotating shaft due to flexible Eigen-modes, with these modes deforming the shaft as a function of the speed of rotation of said shaft.

When such defects are present, the axis of rotation is not immobile and vibrates. It moves away from its theoretical position along a particular trajectory. More specifically, each point on the axis of rotation can move away from its theoretical position, and two points on the axis of rotation at two different ends of the shaft can have a different trajectory.

The properties of a rotating shaft are conventionally understood through a lateral analysis of parameters. The parameters are values of radial quantities such as the position or the radial speed of the shaft, having a non-zero component in a plane orthogonal to the axis of rotation.

The changes in these quantities often need to be characterised depending on whether or not the shaft is rotating. However, many causes can influence the rotational behaviour of a rotating shaft and it is difficult to precisely characterise such behaviour using reliable indicators.

### SUMMARY

Therefore, the aim of the present disclosure is to overcome the aforementioned disadvantages and to propose filtering of a signal to be filtered characterising a rotating shaft.

Therefore, the aim of the present disclosure is a method for filtering at least one signal to be filtered, with the filtering being determined based on measurements representing the movement of a rotating shaft, the method comprising the following steps:
defining at least one characterisation indicator of the rotating shaft, with the characterisation indicator being obtained based on a frequency analysis of the behaviour of the rotating shaft;
determining a filtering template as a function of the characterisation indicator; and
applying the filtering template to said signal to be filtered that is determined based on measurements representing the movement of the rotating shaft.

Thus, this method allows the characterisation indicator to be rendered more reliable and allows some information to be isolated that facilitates the understanding and the rectification of faults on a rotating shaft.

Advantageously, the characterisation indicator is obtained from the following steps:
a) acquiring at least two input signals over a predetermined period, the input signals comprising measurements representing the movement of the rotating shaft, the measurements, associated with a vector quantity, being non-collinear to each other and optionally coplanar with a plane intersecting the axis of rotation of the shaft;
b) determining two components of the input signals, the components being orthogonal to each other and optionally to the axis of rotation;
c) merging the two components into a bivariate signal;
d) time-frequency decomposing the bivariate signal into spectral elements;
e) determining an equivalent ellipse for each spectral element; and
f) extracting the characterisation indicator of the rotating shaft based on parameters of the equivalent ellipse.

The gyroscopic effects and the deformations of the rotor, notably the flexible modes, are simpler to consider subject to a frequency decomposition of the input signals. Indeed, the rotating effects of these deformations are asynchronous, in other words, their frequencies are not directly linked to the rotation frequency of the shaft, and are therefore more easily characterised using a frequency decomposition that can highlight a rotating orbit, also called an equivalent ellipse, for each frequency, with each orbit rotating at a specific speed corresponding to the considered frequency.

This characterisation of a rotating shaft allows applications of the control, identification, modelling, monitoring or diagnostic type.

In one embodiment, the filtering template is applied to the time-frequency decomposition of the bivariate signal so as to obtain a filtered bivariate signal.

In various embodiments, the time-frequency decomposition of the bivariate signal on which the filtering template is applied is a time-frequency decomposition that is obtained using a Fourier, or wavelet, transform, or by filtering, or using a quaternionic Fourier transform.

Advantageously, the method comprises a step of obtaining filtered input signals by projecting the filtered bivariate signal onto the axes collinear with the measured quantities.

In a particular embodiment, the method comprises a step of computing a dual signal of the filtered bivariate signal.

In one embodiment, the at least one indicator includes a polarisation rate, and/or an indicator of circularity and/or amplitude and/or direction and/or orientation and/or synchronisation of an equivalent ellipse.

Advantageously, the filtering template is defined relative to a predefined threshold of a polarisation rate, and/or a circularity indicator of an equivalent ellipse.

Advantageously, the filtering template is defined based on at least one normalised indicator ranging between −1 and 1 or between 0 and 1.

In a particular embodiment, the filtering template is a linear bivariate filter and/or is obtained by multiplying a mask that is determined as a function of the characterisation indicator and of a frequency weighting.

In one embodiment, steps a) to f) are carried out at least a second time for an additional plane intersecting the axis of rotation of the shaft and distinct from said plane, the method further comprising a step of comparing characterisation indicators of the planes.

A further aim of the present disclosure is a computer-implemented method comprising the steps of the method as defined above. The method can be implemented on a real-time target, notably in a magnetic bearing control cabinet.

### BRIEF DESCRIPTION OF THE DRAWINGS

FIG. 1 is a schematic representation of the various steps of a method for obtaining an indicator for the method according to the present disclosure;

FIG. 2 is a representation of an ellipse and of its Euler parameters; and

FIG. 3 is a schematic representation of various filtering steps applicable to a signal to be filtered following the steps of FIG. 1.

### DETAILED DESCRIPTION

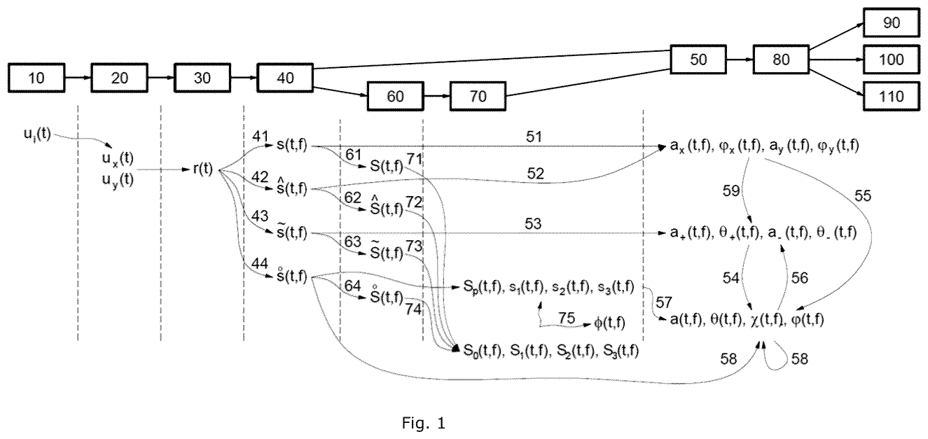

FIG. 1 schematically shows various steps of obtaining an indicator that, in a particular embodiment, can be incorporated into the method according to the present disclosure.

These steps allow the behaviour of a rotating shaft to be characterised. A rotating shaft is understood to be a shaft that is free to rotate about an axis of rotation. The rotating shaft is a shaft of a rotating machine, for example.

In order to implement the method, a step 10 of acquiring input signals is initially carried out.

At least two input signals are acquired over a predetermined period. The predetermined period is several seconds, for example.

The input signals include measurements representing the movement of the rotating shaft. For example, the input signals include measurements of the position, or speed, or acceleration, or force, or magnetic field, or even of the magnetic induction of the rotating shaft. The input signals are acquired, for example, using sensors configured to measure these quantities.

In general, a vector quantity is measured in terms of several spatially distributed components sensitive to the rotation of the shaft. The spatial distribution of these components is used to evaluate the movement of the rotor.

A particular case is that of measurements that are non-collinear to each other and are coplanar with a plane intersecting the axis of rotation of the shaft. Two non-collinear measurements can be used to characterise the behaviour of the rotating shaft in a plane intersecting the axis of rotation of the shaft. Additional measurements allow greater precision for said characterisation.

Measurements that are not coplanar with a plane intersecting the axis of rotation of the shaft nevertheless can be returned by projecting into a reference plane intersecting the axis of rotation of the shaft.

For M measurements with M≥2, M input signals u₁(t) to u_{M}(t) are obtained, with t denoting the time covering the acquisition of the measurements, the set of values of which is denoted by T, in other words dates, which t can assume.

An intersecting plane is understood to be a plane in which the measurements are taken that intersect the axis of rotation of the rotating shaft. The intersecting plane is, for example, orthogonal to the axis of rotation or is not orthogonal to the axis of rotation.

If the intersecting plane is not orthogonal to the axis of rotation, a step 20 is carried out of determining two components of the input signals, with the components being orthogonal to each other and optionally to the axis of rotation. In other words, this step 20 is a change of basis facilitating the subsequent computations.

In the event that the intersecting plane is orthogonal to the axis of rotation, the previous step is intrinsically carried out.

In the event that the axis of rotation is not strictly and precisely defined, with the shaft not always being perfectly cylindrical and/or balanced, and/or non-deformable and/or known, said orthogonal intersecting plane is treated as a study plane that is assumed to be orthogonal to the axis of rotation, or at least sensitive to the rotational movement of the shaft.

In practice, the step 20 of determining the two orthogonal components uₓ(t) and u_{y}(t) is carried out by averaging the projections of the input signals u₁(t) to u_{M}(t) over two orthogonal axes x and y, with these two axes ideally being orthogonal to the axis of rotation. Thus,

$$∀ t ∈ T , \qquad \begin{matrix}{u}_{x} ( t ) = {moy}_{i = [ 1 , M ]} ( {Proj}_{x} ( {u}_{i} ( t ) ) ) \\ {u}_{y} ( t ) = {moy}_{i = [ 1 , M ]} ( {Proj}_{y} ( {u}_{i} ( t ) ) )\end{matrix}$$

the components uₓ(t) and u_{y} (t) are now in the study plane, ideally orthogonal to the axis of rotation.

A step 30 is then carried out of merging the two orthogonal components uₓ(t) and u_{y}(t) into a bivariate signal r(t) in order to combine these two components in an equivalent manner in the form of a complex signal, such that:

$$∀ t ∈ T , \qquad r ( t ) = {u}_{x} ( t ) + 1 i \cdot {u}_{y} ( t )$$

It also can be expressed as follows:

$$r ( t ) = \{ {u}_{x} ( t ) , {u}_{y} ( t ) \}$$

Or even in vector form:

$$r ( t ) = [ \begin{matrix}{u}_{x} ( t ) \\ {u}_{y} ( t )\end{matrix} ]$$

A step 40 is then carried out of frequency decomposing the bivariate signal r(t) into spectral elements characterised by their time-frequency pair (t, f), also called time-frequency cells, with this step being carried out periodically in order to obtain both a temporal and a frequency decomposition, called time-frequency decomposition s(t, f), such that:

$$s ( t , f ) = {spectre}_{t , f} ( r ( τ ) )$$

This time-frequency decomposition step 40 can be carried out in various ways. These various embodiments are described hereafter, with time-frequency decompositions s, or ŝ, or \tilde{s}, or [symbol] being provided in continuous form, in other words, in analogue and not discrete form. A computer-implemented digital implementation then includes a time and frequency sampling step.

In a first embodiment, denoted 41 in FIG. 1, the time-frequency decomposition step 40 is carried out with a filter bank around each frequency f.

Thus, the time-frequency decomposition s(t, f) is expressed as follows:

$$∀ f ∈ {F}_{+} , ∀ t ∈ T , \qquad s ( t , f ) = r ( t ) * {h}_{f} ( t )$$

with h_{f} being the impulse response of a bandpass filter centred around the frequency f, with F₊ being all the frequencies that are greater than or equal to 0.

In a second embodiment 42, the time-frequency decomposition step 40 is carried out using a Fourier transform, in particular a short-term single-sided Fourier transform.

As standard, the time-frequency decomposition is expressed as:

$$∀ f \geq 0 , \begin{matrix}{\hat{s}}_{x} ( t , f ) = \frac{1}{dt} \cdot {\int }_{t - dt}^{t} {u}_{x} ( τ ) \cdot {e}^{- 1 i \text{.2} π . f . τ} \cdot d τ \\ \begin{matrix} & {\hat{s}}_{y} ( t , f ) = \frac{1}{dt} \cdot {\int }_{t - dt}^{t} {u}_{y} ( τ ) \cdot {e}^{- 1 i \text{.2} π . f . τ} \cdot d τ\end{matrix}\end{matrix}$$

In practice, more efficient estimators are preferably used, based on a division into temporal intervals, with time weighting, averaging over several temporal intervals, and overlaps between successive intervals. The formulation is then:

$$\begin{matrix}∀ t ∈ {T}_{↓} , ∀ f ∈ {F}_{+} , & \end{matrix} \begin{matrix}{\hat{s}}_{{x}_{k}} ( t , f ) = {\int }_{t - {dt}_{k}^{-}}^{t + {dt}_{k}^{+}} {u}_{x} ( τ ) \cdot {w}_{k} ( τ - t ) \cdot {e}^{- 1 i \text{.2} π . f . τ} \cdot d τ \\ {\hat{s}}_{{y}_{k}} ( t , f ) = {\int }_{t - {dt}_{k}^{-}}^{t + {dt}_{k}^{+}} {u}_{y} ( τ ) \cdot {w}_{k} ( τ - t ) \cdot {e}^{- 1 i \text{.2} π . f . τ} \cdot d τ\end{matrix}$$

$$∀ t ∈ {T}_{↓} , ∀ f ∈ {F}_{+} , \begin{matrix}{\hat{s}}_{x} ( t , f ) = {moy}_{k = [ 1 , p ]} ( \frac{{\hat{s}}_{{x}_{k}} ( t , f )}{{w}_{k}^{( 1 )}} ) \\ {\hat{s}}_{y} ( t , f ) = {moy}_{k = [ 1 , p ]} ( \frac{{\hat{s}}_{{y}_{k}} ( t , f )}{{w}_{k}^{( 1 )}} )\end{matrix}$$

With dtₖ⁻ and dtₖ⁻ for k=[1, p] defining a division into p intervals, with possible overlap, around a given date t. Conventionally, this division does not depend on t, and is identical for each cell. The temporal extent of interval k is dtₖ=dtₖ⁻+dtₖ⁺.

The overall temporal extent of the corresponding cell (t,f) is:

$${dt}^{+} = {max}_{k = [ 1 , p ]} ( {dt}_{k}^{+} )$$

$${dt}^{-} = {max}_{k = [ 1 , p ]} ( {dt}_{k}^{-} )$$

$$dt = {dt}^{-} + {dt}^{+}$$

With Et wₖ(τ) for τ∈[−dtₖ⁻, dtₖ⁺] for k=[1, p] defining a temporal weighting window for each of these intervals, for example, of the Hanning type. Conventionally, wₖ does not depend on k, which is identical for each interval.

Depending on the estimated spectral quantity, the following compensations need to be introduced:

$$∀ k ∈ [ 1 , p ] ,$$

$$\begin{matrix}{w}_{k}^{( 1 )} = {\int }_{t - {dt}_{k}^{-}}^{+ {dt}_{k}^{+}} {w}_{k} ( τ ) \cdot d τ \\ {w}_{k}^{( 2 )} = {\int }_{t − {dt}_{k}^{−}}^{+ {dt}_{k}^{+}} {w}_{k}^{2} ( τ ) \cdot d τ\end{matrix} ∀ k ∈ [ 1 , p ] ,$$

$$\begin{matrix}{w}_{k}^{( 1 )} = {\int }_{- {dt}_{k}^{-}}^{{dt}_{k}^{+}} {w}_{k} ( τ ) \cdot d τ \\ {w}_{k}^{( 2 )} = {\int }_{− {dt}_{k}^{−}}^{{dt}_{k}^{+}} {w}_{k}^{2} ( τ ) \cdot d τ\end{matrix}$$

In a particular case, the absence of weighting corresponds to wₖ=1, in which case wₖ⁽¹⁾=wₖ⁽²⁾=dtₖ.

In addition, a sub-set of dates is introduced: T_{↑}={t′ᵢ, i=[1, m′]}

In a third embodiment 43, the time-frequency decomposition step 40 is carried out using a Fourier transform, in particular a short-term two-sided Fourier transform, also called “Full spectrum” transform, in other words, for a set F of frequencies taking values from the set of real numbers.

Thus, as standard the time-frequency decomposition \tilde{s}(t, f) is expressed as:

$$∀ f ∈ R , \qquad \tilde{s} ( t , f ) = \frac{1}{dt} \cdot {\int }_{t - dt}^{t} r ( τ ) \cdot {e}^{- 1 i \text{.2} π . f . τ} \cdot d τ$$

Or with a division into temporal blocks:

$$∀ t ∈ {T}_{↓} , ∀ f ∈ F , \qquad {\tilde{s}}_{k} ( t , f ) = {\int }_{t - {dt}_{k}^{-}}^{t + {dt}_{k}^{+}} r ( τ ) \cdot {w}_{k} ( τ - t ) \cdot {e}^{- 1 i \text{.2} π . f . τ} \cdot d τ$$

$$∀ t ∈ {T}_{↓} , ∀ f ∈ F , \tilde{s} ( t , f ) = {moy}_{k = [ 1 , p ]} ( \frac{{\tilde{s}}_{k} ( t , f )}{{w}_{k}^{( 1 )}} )$$

In a fourth embodiment 44, the time-frequency decomposition step 40 is carried out using a Fourier transform, in particular a short-term quaternionic Fourier transform, using the unitary imaginary numbers verifying 1i²=1j²=1k²=1i.1j.1k=−1.

Thus, as standard the time-frequency decomposition s(t, f) is expressed as:

$$\begin{matrix}∀ f \geq 0 , & {{s}^{o}}_{k}\end{matrix} ( t , f ) = \frac{1}{dt} \cdot {\int }_{t - dt}^{t} r ( τ ) \cdot {e}^{- 1 j \text{.2} π . f . τ} \cdot d τ$$

Or with a division into temporal blocks.

$$\begin{matrix}∀ t ∈ {T}_{↓} , ∀ f ∈ {F}_{+} , & {{s}^{o}}_{k} ( t , f ) = {\int }_{t - {dk}_{k}^{-}}^{t + {dk}_{k}^{+}}\end{matrix} r ( τ ) \cdot {w}_{k} ( τ - t ) \cdot {e}^{- 1 i \text{.2} π . f . τ} \cdot d τ$$

$$\begin{matrix}∀ t ∈ {T}_{↓} , ∀ f ∈ {F}_{+} , & {{s}^{o}}_{k} ( t , f ) =\end{matrix} {moy}_{k = [ 1 , p ]} ( \frac{{{s}^{o}}_{k} ( t , f )}{{w}_{k}^{( 1 )}} )$$

The expressions of the Fourier transforms provided in embodiments 41 to 44 above form applicable formulae, producing efficient estimators, notably in terms of their formulation with temporal weighting, averaging over several temporal intervals, overlaps between successive intervals, a more general expression of which can be provided with:

$$( t , f ) = \frac{1}{{dt}_{k}} . {\int }_{t - {dt}_{k}^{-}}^{t + {dt}_{k}^{+}} r ( τ ) \cdot {w}_{k} ( τ ) \cdot {e}^{- 1 μ \text{.2} π . f . τ} \cdot d τ$$

with wᵢ being the temporal weighting, and u being defined such that 1μ²=−1.

Finally,

$$\overbrace{s} ( t , f ) = {moy}_{k} ( ( t , f ) )$$

The index k applied to wₖ (above) or pₖ (below) means that the weighting can differ from one interval to another.

In addition, other frequency transforms can be used, such as wavelet decompositions.

A more general expression is:

$$( t , f ) = {\int }_{t - {dt}_{k}^{-}}^{t + {dt}_{k}^{+}} r ( τ ) \cdot {p}_{k} ( τ , f ) \cdot d τ$$

Even more generally, the time division and the weighting can be varied as a function of the time-frequency cell (t, f):

$$( t , f ) = {\int }_{t - {dt}_{k}^{-} ( t , f )}^{t + {dt}_{k}^{+} ( t , f )} r ( τ ) \cdot {p}_{k} ( t , f ) ( τ ) \cdot d τ$$

The trajectory (orbit) is obtained by inverse transformation, of the following type:

$$s ( t , f ) ( τ ) = {\int }_{f - {df}^{-} ( t , f )}^{f + {df}^{+} ( t , f )} ( \overbrace{s} ( t , v ) \cdot q ( t , f ) ( τ , v ) + \overbrace{s} ( t , - v ) \cdot q ( t , f ) ( τ , - v ) ) \cdot dv$$

With the frequency extent of the cell (t, f) then being df=df⁺+df⁻, the temporal extent of the cell (t, f) being dt=dt⁺+dt⁻.

From each spectral element s(t, f), at a fixed date t and frequency f, it is possible to deduce an equivalent ellipse from the instantaneous orbit. This can be referred to as local in the temporal and frequency sense, in other words, at the date t and frequency f.

Therefore, a step 50 is carried out of determining the equivalent ellipse for each spectral element. Irrespective of the time-frequency decomposition method, the instantaneous orbit can be expressed in the form of a parametric equation such that, for each component x and y, and with sₓ_{ₒ}, s_{y}_{ₒ}, and Øₓ, Ø_{y} being the instantaneous amplitudes and phases:

$${s}_{x} ( t , f ) = {s}_{{x}_{o}} ( t , f ) \cdot cos ( {∅}_{x} ( t , f ) )$$

$${s}_{y} ( t , f ) = {s}_{{y}_{o}} ( t , f ) \cdot cos ( {∅}_{y} ( t , f ) )$$

For a fixed frequency f, covering the time t allows the trajectory to be obtained at this frequency.

This instantaneous orbit assumes the form of an equivalent ellipse, provided that sₓ(t, f), s_{y}(t, f)), \dot{Ø}ₓ(t, f), \dot{Ø}_{y}(t, f) vary slowly as a function of time, for example, during a complete revolution at the frequency f, and in any case for the duration dt of the temporal interval defining the spectral element.

In this case, the date t of the considered spectral element can be distinguished from the time τ that evolves in this spectral element. In addition, by introducing the frequency f into the expression of the phases that are assumed to be quasi-linear, the equivalent ellipse is obtained in the form of a temporal parametric equation for each component x and y:

$${{s}^{′}}_{x} ( t , f ) ( τ ) = {a}_{x} ( t , f ) \cdot cos ( 2 \cdot π \cdot f \cdot τ + {φ}_{x} ( t , f ) )$$

$${{s}^{′}}_{y} ( t , f ) ( τ ) = {a}_{y} ( t , f ) \cdot cos ( 2 \cdot π \cdot f \cdot τ + {φ}_{y} ( t , f ) )$$

These parametric equations also can be written as follows, for example:

$${{s}^{′}}_{x} ( t , f ) ( τ ) = {a}_{x} ( t , f ) \cdot ( cos ( 2 \cdot π \cdot f \cdot τ ) \cdot cos ( {φ}_{x} ( t , f ) ) - sin ( 2 \cdot π \cdot f \cdot τ ) \cdot sin ( {φ}_{x} ( t , f ) ) )$$

$${{s}^{′}}_{y} ( t , f ) ( τ ) = {a}_{y} ( t , f ) . ( cos ( 2 \cdot π \cdot f \cdot τ ) \cdot cos ( {φ}_{y} ( t , f ) ) - sin ( 2 \cdot π \cdot f \cdot τ ) \cdot sin ( {φ}_{y} ( t , f ) ) )$$

In order to obtain these parametric equations, notably in the case of a frequency decomposition using a filter bank, the parameters aₓ(t, f), φₓ(t, f), a_{y}(t, f), φ_{y}(t, f) of the equivalent ellipse can be obtained by estimates, such as direct or quadratic averaging or by RMS value, from the instantaneous quantities (τ, f) pour τ∈[t−dt⁻, t+dt⁺].

In the case of a frequency decomposition using a Fourier transform, the parametric equation of the equivalent ellipse is obtained using an inverse Fourier transform of the frequency element:

$${{s}^{′}}_{x} ( t , f ) ( τ ) = 2 \cdot Re ( {\hat{s}}_{x} ( t , f ) \cdot {e}^{1 i \text{.2} . π . f . τ} )$$

$${{s}^{′}}_{y} ( t , f ) ( τ ) = 2 \cdot Re ( {\hat{s}}_{y} ( t , f ) \cdot {e}^{1 i \text{.2} π . f . τ} )$$

By forming the associated complex quantity ś (t, f)=Śₓ(t, f)+1i.Ś_{y}(t, f), in other words, the bivariate representation, it is possible to highlight the decomposition of a parametric equation of the equivalent ellipse in two circles in opposite directions:

$${s}^{′} ( t , f ) ( τ ) = a\_ ( t , f ) \cdot {e}^{1 i \cdot {θ}_{+} ( t , f )} \cdot {e}^{1 i \cdot 2 \cdot π \cdot f \cdot τ} + {a}_{+} ( t , f ) \cdot {e}^{- 1 i \cdot θ\_ ( t , f )} \cdot {e}^{- 1 i \cdot 2 \cdot π \cdot f \cdot τ}$$

With the following parameters obtained following a computation step 59:

$${a}_{+} = \frac{a}{2} \cdot \sqrt{{a}_{x}^{2} + {a}_{y}^{2} + 2 \cdot {a}_{x} \cdot {a}_{y} \cdot sin ( {φ}_{x} - {φ}_{y} )}$$

$${a}_{-} = \frac{a}{2} \cdot \sqrt{{a}_{x}^{2} + {a}_{y}^{2} + 2 \cdot {a}_{x} \cdot {a}_{y} \cdot sin ( {φ}_{y} - {φ}_{x} )}$$

$${θ}_{+} = arc tan 2 ( {a}_{x} \cdot sin ( {φ}_{x} ) + {a}_{y} \cdot cos ( {φ}_{y} ) , {a}_{x} \cdot cos ( {φ}_{x} ) - {a}_{y} \cdot sin ( {φ}_{y} ) )$$

$${θ}_{-} = arc tan 2 ( {a}_{x} \cdot sin ( {φ}_{x} ) - {a}_{y} \cdot cos ( {φ}_{y} ) , {a}_{x} \cdot cos ( {φ}_{x} ) + {a}_{y} \cdot sin ( {φ}_{y} ) )$$

The characterisation of the equivalent ellipse is straightforward using the two-sided (“full spectrum”) Fourier transform, which can be directly written in polar form:

$$∀ f > 0 , \begin{matrix}\tilde{s} ( t , f ) = {a}_{+} ( t , f ) \cdot {e}^{1 i \cdot {θ}_{+} ( t , f )} \\ \tilde{s} ( t , - f ) = {a}_{-} ( t , f ) \cdot {e}^{- 1 i \cdot {θ}_{-} ( t , f )}\end{matrix}$$

In general, an equivalent ellipse can be determined and plotted by obtaining its Euler parameters.

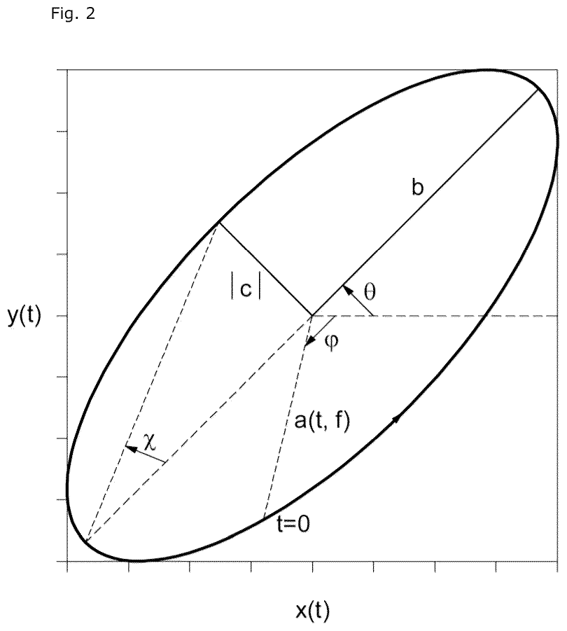

FIG. 2 shows an example of an ellipse and its Euler parameters a(t, f), θ(t, f), χ(t,f), φ(t, f), which fully define an equivalent ellipse, with:

$$a \geq 0$$

$$θ ∈ [ - π / 2 , π / 2 ]$$

$$χ ∈ [ - π / 4 , π / 4 ]$$

$$φ ∈ [ - π , π ]$$

Furthermore, b is the semi-major axis, in other words, the major radius, and c is the semi-minor axis, in other words, the minor radius, the sign of which provides the direction of rotation of the equivalent ellipse.

The parametric equation of the trajectory of the equivalent ellipse is more practical in complex form, since:
an equation of a circle is notably expressed as cos and sin of the same phase;
the axes are dilated in order to obtain an ellipse;
a rotation is applied thereto in order to obtain the desired direction, thus:

$${s}^{′} ( t , f ) ( τ ) = a ( t , f ) \cdot {e}^{1 i \cdot θ ( t , f )} \cdot ( cos ( χ ( t , f ) ) \cdot cos ( 2 \cdot π \cdot f \cdot τ + φ ( t , f ) ) + 1 i \cdot sin ( χ ( t , f ) ) \cdot sin ( 2 \cdot π \cdot f \cdot τ + φ ( t , f ) ) )$$

Direction is understood to mean the angle θ of the equivalent ellipse between the major axis and the x-axis. Orientation is understood to mean the direction of rotation describing the trajectory of said ellipse.

This characterisation of the equivalent ellipse is natural with the time-frequency decomposition using a quaternionic Fourier transform, which can be directly placed into Euler form:

$${s}^{o} ( t , f ) = \vert {s}^{o} ( t , f ) \vert \cdot {e}^{1 i \cdot θ ( t , f )} \cdot {e}^{- 1 k \cdot χ ( t , f )} \cdot {e}^{1 j \cdot φ ( t , f )}$$

This parametric equation has the particular advantage of rejecting the temporal parametrisation towards a single exponential term e^{1j.2.π.f.τ} when the inverse Fourier transform is applied to the frequency element in order to obtain the temporal parametric equation of the trajectory of the equivalent ellipse:

$${s}^{′} ( t , f ) ( τ ) \approx \vert {s}^{o} ( t , f ) \vert \cdot {p}_{{roj}_{{C}_{1 i}}} ( {e}^{1 i \cdot θ ( t , f )} \cdot {e}^{- 1 k \cdot χ ( t , f )} \cdot {e}^{1 j \cdot φ ( t , f )} \cdot {e}^{1 j \cdot 2 \cdot π \cdot f \cdot τ} )$$

with Proj_{C}_{₁ᵢ} being a projection into the set of complex numbers C₁ᵢ.

More specifically, the step 50 of determining the equivalent ellipse includes a step of computing the Euler parameters of said equivalent ellipse.

Starting from the time-frequency decomposition using a filter bank, a step 51 of computing aₓ and a_{y} is obtained such that:

$$∀ τ ∈ {T}_{↓} , ∀ f ∈ {F}_{+}^{*} , \begin{matrix}{a}_{x} ( t , f ) = \sqrt{\frac{2}{d t} \cdot {\int }_{t - {dt}^{-}}^{t + {dt}^{+}} {s}_{x}^{2} ( τ , f ) \cdot d τ} \\ {a}_{y} ( t , f ) = \sqrt{\frac{2}{d t} \cdot {\int }_{t - {dt}^{-}}^{t + {dt}^{+}} {s}_{y}^{2} ( τ , f ) \cdot d τ}\end{matrix}$$

with T_{↑} being a sub-set of T.

Starting from the time-frequency decomposition using a short-term single-sided Fourier transform, a step 52 of computing aₓ, a_{y}, φₓ and φ_{y} is obtained such that:

$$∀ t ∈ {T}_{↓} , ∀ f ∈ {F}_{+}^{*} , \begin{matrix}{a}_{x} ( t , f ) = 2 \cdot \vert {\hat{s}}_{x} ( t , f ) \vert {φ}_{x} ( t , f ) = Arg ( {\hat{s}}_{x} ( t , f ) ) \\ {a}_{y} ( t , f ) = 2 \cdot \vert {\hat{s}}_{y} ( t , f ) \vert {φ}_{y} ( t , f ) = Arg ( {\hat{s}}_{y} ( t , f ) )\end{matrix}$$

Starting from the time-frequency decomposition using a short-term two-sided Fourier transform, a step 53 of computing a₊, a₋, θ₊ and θ₋ is obtained such that:

$$∀ t ∈ {T}_{↓} , ∀ f ∈ {F}_{+}^{*} , \begin{matrix}{a}_{+} ( t , f ) = \vert \tilde{s} ( t , f ) \vert {θ}_{+} ( t , f ) = Arg ( \tilde{s} ( t , f ) ) \\ {a}_{-} ( t , f ) = \vert \tilde{s} ( t , - f ) \vert {θ}_{-} ( t , f ) = - Arg ( \tilde{s} ( t , - f ) )\end{matrix}$$

An additional computation step 54 or 55 yields the following Euler parameters:

$$a = \sqrt{2} \cdot \sqrt{{a}_{+}^{2} + {a}_{-}^{2}} a = \sqrt{{a}_{x}^{2} + {a}_{y}^{2}}$$

$$φ = \frac{{θ}_{+} + {θ}_{-}}{2} ou φ = \frac{{φ}_{x} + {φ}_{y}}{2}$$

$$θ = \frac{{θ}_{+} + {θ}_{-}}{2} θ = \frac{1}{2} \cdot arctan 2 ( 2 \cdot {a}_{x} \cdot {a}_{y} \cdot cos ( {φ}_{x} - {φ}_{y} ) , {a}_{x}^{2} - {a}_{y}^{2} )$$

$$χ = arctan 2 ( {a}_{+} - {a}_{-} , {a}_{+} + {a}_{-} ) χ = \frac{1}{2} \cdot arcsin ( ratio * ( 2 \cdot {a}_{x} \cdot {a}_{y} , {a}_{x}^{2} + {a}_{y}^{2} ) \cdot sin ( {φ}_{x} - {φ}_{y} ) )$$

An inverse computation step 56 is also possible, such that:

$${a}_{+} = \frac{a}{2} \cdot ( cos ( χ ) + sin ( χ ) )$$

$${a}_{-} = \frac{a}{2} \cdot ( cos ( χ ) - sin ( χ ) )$$

$${θ}_{+} = φ + θ$$

$${θ}_{-} = φ - θ$$

The method optionally comprises a step 60 of computing the spectral density of the time-frequency decomposition. The spectral densities of each component and the cross-spectral densities between components are used to estimate the energy distribution between the x and y components.

Starting from the time-frequency decomposition using a filter bank, a step 61 of computing the spectral density S is obtained such that:

$$∀ t ∈ {T}_{↓} , ∀ f ∈ {F}_{+} , \begin{matrix}{S}_{x} ( t , f ) = \frac{1}{d t} \cdot {\int }_{t - {dt}^{-}}^{t + {dt}^{+}} {s}_{x}^{2} ( τ , f ) \cdot d τ \\ {S}_{y} ( t , f ) = \frac{1}{d t} \cdot {\int }_{t - {dt}^{-}}^{t + {dt}^{+}} {s}_{y}^{2} ( τ , f ) \cdot d τ \\ {S}_{x y} ( t , f ) = \frac{1}{d t} \cdot {\int }_{t - {dt}^{-}}^{t + {dt}^{+}} {s}_{x} ( τ , f ) \cdot {s}_{y} ( τ , f ) \cdot d τ\end{matrix}$$

Starting from the time-frequency decomposition using a short-term single-sided Fourier transform, a step 62 of computing the spectral density Ŝ is obtained such that:

$$∀ t ∈ {T}_{↓} , ∀ f ∈ {F}_{+}^{*} , \begin{matrix}{\hat{S}}_{x} ( t , f ) = 2 \cdot df \cdot {moy}_{k = [ 1 , p ]} ( \frac{{\vert {\hat{s}}_{{x}_{k}} ( t , f ) \vert}^{2}}{{w}_{k}^{( 2 )}} ) \\ {\hat{S}}_{y} ( t , f ) = 2 \cdot df \cdot {moy}_{k = [ 1 , p ]} ( \frac{{\vert {\hat{s}}_{{y}_{k}} ( t , f ) \vert}^{2}}{{w}_{k}^{( 2 )}} ) \\ {\hat{S}}_{x y} ( t , f ) = 2 \cdot df \cdot {moy}_{k = [ 1 , p ]} ( \frac{{\hat{s}}_{{x}_{k}} ( t , f ) \cdot \overline{{\hat{s}}_{{y}_{k}} ( t , f} )}{{w}_{k}^{( 2 )}} )\end{matrix}$$

Starting from the time-frequency decomposition using a short-term two-sided Fourier transform, a step 63 of computing the spectral density \tilde{S} is obtained such that:

$$∀ τ ∈ {T}_{↓} , ∀ f ∈ {F}^{*} , \tilde{S} ( t , f ) = df \cdot {moy}_{k = [ 1 , p ]} ( \frac{{\vert {\tilde{s}}_{k} ( t , f ) \vert}^{2}}{{w}_{k}^{( 2 )}} )$$

The following also will be used:

$$∀ t ∈ {T}_{↓} , ∀ f ∈ {F}_{+}^{*} , \tilde{{S}_{*}} ( t , f ) = df \cdot {moy}_{k = [ 1 , p ]} ( \frac{{\tilde{s}}_{k} ( t , f ) \cdot {\tilde{s}}_{k} ( t , - f )}{{w}_{k}^{( 2 )}} )$$

Starting from the time-frequency decomposition using a short-term quaternionic Fourier transform, a step 64 of computing the spectral density [symbol] is obtained such that:

$$∀ t ∈ {T}_{↓} , ∀ f ∈ {F}_{+} , \\ {S}^{o} ( t , f ) = df \cdot {moy}_{k = [ 1 , p ]} ( \frac{{\vert {{s}_{k}}^{o} ( t , f ) \vert}^{2}}{{w}_{k}^{( 2 )}} ) + df \cdot {moy}_{k = [ 1 , p ]} ( \frac{{{s}_{k}}^{o} ( t , f ) \cdot 1 j \cdot \overline{{{s}_{k}}^{o} ( t , f )}}{{w}_{k}^{( 2 )}} )$$

Based on these spectral densities S, Ŝ, \tilde{S}, and [symbol] , a step 70 is carried out of computing the Stokes parameters S₀, S₁, S₂, and S₃ of at least one equivalent ellipse.

The Stokes parameters are four real numbers and are conventionally used to describe the polarisation state of an electromagnetic wave.

S₀ is commonly the total intensity of an electromagnetic wave and in this case by extension represents the total intensity of the bivariate signal, S₀>0.

S₁ and S₂ provide the intensity of rectilinear polarisation \sqrt{S₁²+S₂²}, as well as the direction of the polarisation of the ellipse

$$θ = \frac{1}{2} .$$

a tan 2(S₂, S₁).

S₃ provides the circular polarisation intensity |S₃|, with its sign providing the direction of rotation.

The reduced Stokes parameters are also defined:

$$si {S}_{0} \neq 0 , ∀ i ∈ \{ 1 , 2 , 3 \} {s}_{i} {=}^{def} \frac{{S}_{i}}{{S}_{0}}$$

Starting from the spectral density obtained for the time-frequency decomposition using a filter bank, a step 71 of computing the Stokes parameters of at least one equivalent ellipse is obtained such that:

$$∀ t ∈ {T}_{↓} , ∀ f ∈ {F}_{+}^{*} , \begin{matrix}{S}_{0} ( t , f ) = 2 \cdot ( {S}_{x} ( t , f ) + {S}_{y} ( t , f ) ) \\ {S}_{1} ( t , f ) = 2 \cdot ( {S}_{x} ( t , f ) - {S}_{y} ( t , f ) )\end{matrix}$$

Starting from the spectral density obtained for the time-frequency decomposition using a short-term single-sided Fourier transform, a step 72 of computing the Stokes parameters of at least one equivalent ellipse is obtained such that:

$$∀ t ∈ {T}_{↓} , ∀ f ∈ {F}_{+}^{*} , \begin{matrix}\begin{matrix}\begin{matrix}{S}_{0} ( t , f ) = 2 \cdot ( {\hat{S}}_{x} ( t , f ) + {\hat{S}}_{y} ( t , f ) ) \\ {S}_{1} ( t , f ) = 2 \cdot ( {\hat{S}}_{x} ( t , f ) - {\hat{S}}_{y} ( t , f ) )\end{matrix} \\ {S}_{2} ( t , f ) = 4 \cdot Re ( {\hat{S}}_{x y} ( t , f ) )\end{matrix} \\ {S}_{3} ( t , f ) = 4 \cdot Im ( {\hat{S}}_{x y} ( t , f ) )\end{matrix}$$

Starting from the spectral density obtained for the time-frequency decomposition using a short-term two-sided Fourier transform, a step 73 of computing the Stokes parameters of at least one equivalent ellipse is obtained such that:

$$∀ t ∈ {T}_{↓} , ∀ f ∈ {F}_{+}^{*} , \begin{matrix}\begin{matrix}\begin{matrix}{S}_{0} ( t , f ) = 2 \cdot ( \tilde{S} ( t , f ) + \tilde{S} ( t , - f ) ) \\ {S}_{1} ( t , f ) = 4 \cdot Re ( \tilde{{S}_{*}} ( t , f ) )\end{matrix} \\ {S}_{2} ( t , f ) = 4 \cdot lm ( \tilde{{S}_{*}} ( t , f ) )\end{matrix} \\ {S}_{3} ( t , f ) = 2 \cdot ( \tilde{S} ( t , f ) - \tilde{S} ( t , - f ) )\end{matrix}$$

Starting from the spectral density obtained for the time-frequency decomposition using a short-term quaternionic Fourier transform, a step 74 of computing the Stokes parameters of at least one equivalent ellipse is obtained such that:

$$t ∈ {T}_{↓} , ∀ f ∈ {F}_{+} , \begin{matrix}\begin{matrix}\begin{matrix}{S}_{0} ( t , f ) = Re ( {S}^{o} ( t , f ) ) \\ {S}_{1} ( t , f ) = {Im}_{1 j} ( {S}^{o} ( t , f ) )\end{matrix} \\ {S}_{2} ( t , f ) = {Im}_{1 k} ( {S}^{o} ( t , f ) )\end{matrix} \\ {S}_{3} ( t , f ) = {Im}_{1 i} ( {S}^{o} ( t , f ) )\end{matrix}$$

As an alternative embodiment, the Stokes parameters S₁, S₂, and S₃ are directly computed using the time-frequency decomposition using a quaternionic Fourier transform:

$$∀ t ∈ {T}_{↓} , ∀ f ∈ {F}_{+} , \begin{matrix}\begin{matrix}\begin{matrix}{σ}^{o} ( t , f ) = {s}^{o} ( t , f ) \cdot 1 j \cdot \overline{{s}^{o} ( t , f )} \\ {S}_{1} ( t , f ) = {Im}_{1 j} ( {σ}^{o} ( t , f ) )\end{matrix} \\ {S}_{2} ( t , f ) = {Im}_{1 k} ( {σ}^{o} ( t , f ) )\end{matrix} \\ {S}_{3} ( t , f ) = {Im}_{1 i} ( {σ}^{o} ( t , f ) )\end{matrix}$$

Based on these Stokes parameters, a step 75 is carried out of computing the polarisation rate Ø, as well as the aforementioned reduced Stokes parameters, as well as the polarised part of the intensity Sₚ.

$$∀ t ∈ {T}_{↓} , ∀ f ∈ {F}_{+} , \begin{matrix}\begin{matrix}∀ i ∈ \{ 1 , 2 , 3 \} {s}_{i} ( t , f ) = {ratio}^{*} ( {S}_{i} ( t , f ) , {S}_{0} ( t , f ) ) \\ ∅ ( t , f ) = \sqrt{{s}_{1}^{2} ( t , f ) + {s}_{2}^{2} ( t , f ) + {s}_{3}^{2} ( t , f )}\end{matrix} \\ {S}_{p} ( t , f ) = ∅ ( t , f ) \cdot {S}_{0} ( t , f )\end{matrix}$$

The polarisation expressed by the polarisation rate Ø highlights the cyclo-stationarity of an equivalent ellipse, namely, the regularity of the trajectory of said ellipse relative to a period of revolution. The polarisation reflects the structuring of said trajectory relative to defined frequencies. The polarisation rate thus can be computed for each time-frequency cell resulting from the time-frequency decomposition in order to highlight the cyclo-stationarity of the rotating shaft for a given frequency.

In addition, a computation step 57 can be implemented in order to determine the Euler parameters a, θ, and χ based on the polarisation spectral density Sₚ and the reduced Stokes parameters:

$$∀ t ∈ {T}_{↓} , ∀ f ∈ {F}_{+}^{*} , \begin{matrix}\begin{matrix}a ( t , f ) = \sqrt{{S}_{p} ( t , f )} \\ θ ( t , f ) = \frac{1}{2} \cdot arc tan 2 ( {s}_{2} ( t , f ) , {s}_{1} ( t , f ) )\end{matrix} \\ χ ( t , f ) = \frac{1}{2} ( {ratio}^{*} ( {s}_{3} ( t , f ) , {S}_{p} ( t , f ) ) )\end{matrix}$$

A fourth Euler parameter φ providing the phase that is the source of the trajectory also can be deduced from the following computation step 58:

$$∀ t ∈ {T}_{↓} , ∀ f ∈ {F}_{+}^{*} , φ ( t , f ) = Arg ( Pro {j}_{{C}_{1 j}} ( {e}^{1 k \cdot χ ( t , f )} \cdot {e}^{- 1 i \cdot θ ( t , f )} \cdot {s}^{o} ( t , f ) ) )$$

Following the step 50 of determining an equivalent ellipse, notably by computing the Euler parameters of said equivalent ellipse, a step 80 of extracting at least one characterisation indicator of the rotating shaft from parameters of the equivalent ellipse, for example, Euler or Stokes parameters or parameters derived therefrom, is carried out.

In addition, the preceding steps are optionally carried out at least a second time for an additional plane intersecting the axis of rotation of the shaft and distinct from the plane for which these steps were initially carried out. In this embodiment, it is thus possible to carry out a step of comparing the characterisation indicators of the planes.

For example, the at least one characterisation indicator includes the previously described polarisation rate Ø, and/or a circularity indicator (linked to |χ|), and/or an intensity indicator and/or an amplitude indicator, and/or a direction of rotation indicator (linked to the sign of χ), and/or a direction indicator (linked to θ), and/or synchronisation indicator (linked to φ) of the equivalent ellipse.

Each elementary indicator helps to provide a practical and useful characteristic of the rotating system, for example, a high rate of polarisation and a high degree of circularity are probably due to the rotating shaft. Distinguishing this part of the signal, with the complementary part being treated as disturbances, can be useful, for example, for identifying said shaft (for modelling purposes) or for better controlling it in the case of a shaft equipped with magnetic bearings.

Optionally, the at least one characterisation indicator is normalised, in other words, its value ranges between −1 and 1 or between 0 and 1.

The characterisation indicator is provided for one plane, it is then denoted A, or by a comparison between two planes, it is then denoted I.

The characterisation indicator is referred to as a criterion, denoted C, when it is constructed from any characteristic quantity re-evaluated at each instant t. The characterisation indicator is referred to as stationarity, denoted S, when it is based on the stationarity of a quantity over time (maximum when the variation of said variable over time is zero).

Thus, the polarisation rate indicator is denoted:

$$∀ t ∈ {T}_{↓} , ∀ f ∈ {F}_{+} , A {C}_{p o l arisation} ( t , f ) = Φ ( t , f )$$

For one plane, the intensity indicator is:

$$∀ t ∈ {T}_{↓} , ∀ f ∈ {F}_{+} , A {C}_{intensité} ( t , f ) = {normalise}_{τ ∈ {T}_{↓} , ν ∈ {F}_{+}} ( {S}_{0} ( t , f ) )$$

With the normalisation function:

$$∀ t ∈ T T , ∀ f ∈ FF , {normalise}_{τ ∈ TT , ν ∈ FF} ( x ( t , f ) ) = \frac{x ( t , f )}{{max}_{τ ∈ TT , ν ∈ FF}^{*} ( \vert x ( τ , ν ) \vert )}$$

TT and FF denote sets of generic dates and frequencies, taking their values from the set of real values R.

For one plane, the amplitude indicator is:

$$∀ t ∈ {T}_{↓} , ∀ f ∈ {F}_{+} , {AC}_{amplitude} ( t , f ) = {normalise}_{τ ∈ {T}_{↓} , v ∈ {F}_{+}} ( a ( t , f ) )$$

For one plane, the sign indicator is −1 or 1 depending on the sign of x:

$$∀ t ∈ {T}_{↓} , ∀ f ∈ {F}_{+} , {AC}_{signe} ( t , f ) = signe ( χ ( t , f ) )$$

For one plane, the circularity indicator is:

$$∀ t ∈ {T}_{↓} , ∀ f ∈ {F}_{+} , {AC}_{circularit {e}^{′}} ( t , f ) = \frac{\vert χ ( t , f ) \vert}{π / 4}$$

For one plane, the sign stationarity indicator, in other words, the direction of rotation, in other words, the orientation, is:

$$∀ t ∈ {T}_{↓} , ∀ f ∈ {F}_{+} , {AS}_{signe} ( t , f ) = autostat ( {AC}_{signe} ( t , f ) , tol = 0 )$$

With the stationarity function:

$$∀ t ∈ TT , \begin{matrix}pour tol > 0 : autostat ( x ( t ) , tol ) = {e}^{- \frac{\vert dx ( t ) \vert}{tol}} \\ pour tol = 0 : autostat ( x ( t ) , 0 ) = ( dx ( t ) == 0 )\end{matrix}$$

For one plane, the circularity stationarity indicator is:

$$∀ t ∈ {T}_{↓} , ∀ f ∈ {F}_{+} , {AS}_{circularit {e}^{′}} ( t , f ) = autostat ( {AC}_{circularit {e}^{′}} ( t , f ) , tol = 0.1 )$$

For one plane, the direction stationarity indicator, in other words, the geometric inclination of the ellipse, is:

$$∀ t ∈ {T}_{↓} , ∀ f ∈ {F}_{+} , {AS}_{direction} ( t , f ) = autostat ( θ ( t , f ) , tol = 10 \cdot π / 180 )$$

For one plane, the synchronisation stationarity indicator is:

$$∀ t ∈ {T}_{↓} , ∀ f ∈ {F}_{+} , {AS}_{synchro} ( t , f ) = autostat ( φ ( t , f ) , tol = 10 \cdot π / 180 )$$

For two planes, each parameter or indicator is redefined for an additional plane, by denoting these new parameters with an apostrophe, for example, a′.

The amplitude comparative characterisation indicator is:

$$∀ t ∈ {T}_{↓} , ∀ f ∈ {F}_{+} , {IC}_{amplitude} ( t , f ) = {normalise}_{t ∈ {T}_{↓} , v ∈ {F}_{+}} ( \sqrt{a ( t , f ) \cdot {a}^{′} ( t , f )} )$$

The sign comparative characterisation indicator is a Boolean between 0 and 1 depending on the result of the following test:

$$∀ t ∈ {T}_{↓} , ∀ f ∈ {F}_{+} , {IC}_{signe} ( t , f ) = ( {AC}_{signe} ( t , f ) == {AC}_{signe}^{′} ( t , f ) )$$

The circularity comparative characterisation indicator is:

$$∀ t ∈ {T}_{↓} , ∀ f ∈ {F}_{+} , {IC}_{circularit {e}^{′}} ( t , f ) = 1 - reldif ( {AC}_{circularit {e}^{′}} ( t , f ) , {AC}_{circularit {e}^{′}}^{′} ( t , f ) )$$

With the relative error function such that:

$$reldif ( x , y ) = {ratio}^{*} ( 2 \cdot \vert x - y \vert , \vert x \vert + \vert y \vert )$$

And with the division function with exception such that:

$${ratio}^{*} ( x , y ) = \begin{matrix}x / y & si y \neq 0 \\ 0 & sinon\end{matrix}$$

The direction comparative characterisation indicator, in other words, the geometric inclination of the ellipse, is:

$$∀ t ∈ {T}_{↓} , ∀ f ∈ {F}_{+} , {IC}_{direction} ( t , f ) = 1 - reldif ( θ ( t , f ) , {θ}^{′} ( t , f ) )$$

The synchronisation comparative characterisation indicator is:

$$∀ t ∈ {T}_{↓} , ∀ f ∈ {F}_{+} , {IC}_{synchro} ( t , f ) = 1 - reldif ( φ ( t , f ) , {φ}^{′} ( t , f ) )$$

The stationarity and comparative circularity characterisation indicator is:

$$∀ t ∈ {T}_{↓} ∀ f ∈ {F}_{+} , {IS}_{circularit {e}^{'}} ( t , f ) = autostat ( {AC}_{circularit {e}^{'}} ( t , f ) - {AC}_{circularit {e}^{'}}^{′} ( t , f ) , tol = 0.1 )$$

The stationarity and comparative direction characterisation indicator is:

$$∀ t ∈ {T}_{↓} ∀ f ∈ {F}_{+} , {IS}_{direction} ( t , f ) = autostat ( θ ( t , f ) - {θ}^{′} ( t , f ) , tol = 10. π / 180 )$$

The stationarity and comparative synchronisation characterisation indicator is:

$$∀ t ∈ {T}_{↓} ∀ f ∈ {F}_{+} , {IS}_{synchro} ( t , f ) = autostat ( φ ( t , f ) - {φ}^{′} ( t , f ) , tol = 10. π / 180 )$$

Other indicators can be constructed from the quantities constructed in steps 70 and 50.

Optionally, a step 90 is carried out of introducing the at least one characterisation indicator into a neural network in order to classify said indicator as a function of the rotation of the shaft and to link it to a previously listed anomaly. Anomalies similar to the learning base are then detected.

Optionally, a step 100 is carried out of displaying the at least one extracted characterisation indicator so that it can be read by an operator and so that they can understand potential anomalies in the rotating shaft.

A step 110 of displaying an image of the trajectory of at least one equivalent ellipse also can be carried out.

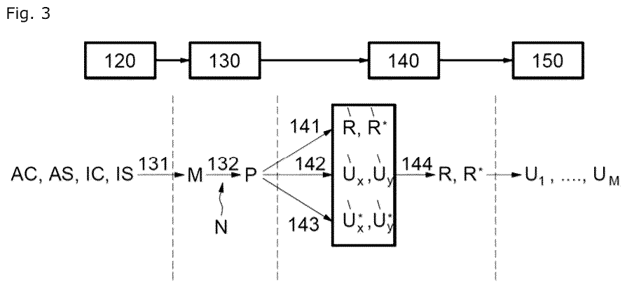

FIG. 3 schematically shows the steps of the filtering method according to one example the present disclosure. In a particular embodiment, the following steps are carried out following the step 80 of extracting a characterisation indicator.

The filtering method is intended to filter at least one signal to be filtered, for example, a signal determined based on measurements representing the movement of a rotating shaft. The method may or may not be carried out in real time. Said signal can be one of the input signals determined in step 10, and/or one of the components of the input signals determined in step 20, and/or even the bivariate signal determined in step 30.

In order to carry out this filtering method, a step 120 of defining at least one characterisation indicator of the rotating shaft is initially carried out, with the characterisation indicator being obtained from a frequency analysis of the behaviour of the rotating shaft.

In a particular embodiment, the characterisation indicator is an indicator extracted during step 80 described above.

Thus, the at least one characterisation indicator includes the previously described polarisation rate Ø, and/or a circularity indicator, and/or an intensity indicator and/or an amplitude indicator, and/or a direction of rotation indicator, and/or a direction indicator, and/or a synchronisation indicator of the equivalent ellipse.

A step 130 is then carried out of determining a filtering template as a function of the at least one characterisation indicator.

The step 130 of determining a filtering template comprises, for example, a step 131 of computing a mask, such that:

$$∀ t ∈ {T}_{↓} ∀ f ∈ {F}_{+} , M ( t , f ) = {combine}_{i , j , k , l} ( {AC}_{{item}_{i}} ( t , f ) , {AS}_{{item}_{j}} ( t , f ) , {IC}_{{item}_{k}} ( t , f ) , {IS}_{{item}_{l}} ( t , f ) )$$

Where combine is a function that as input takes one or more characterisation indicators at values within [0.1] or [−1.1] and as output renders a real value within [0.1].

Following the step 131 of computing the mask M, a step 132 is carried out of computing the filtering template P and its dual P*, such that:

$$∀ t ∈ {T}_{↓} ∀ f ∈ {F}_{+} , \qquad \begin{matrix}P ( t , f ) = M ( t , f ) . N ( t , f ) \\ {P}^{*} ( t , f ) = {M}^{*} ( t , f ) . N ( t , f )\end{matrix}$$

With N being a frequency weighting with values within [0.1]. N is a random frequency weighting, independent of M and is similar to conventional frequency filtering. N allows, for example, a frequency band to be focused upon around the speed of the shaft.

In addition, the dual mask (complementary): M*=1−M

The advantage of considering M* and then P* is that, depending on the application, it is possible to focus on a certain portion of the signal, obtained according to the characterisation indicators used, provided by M and/or the residue equated with disturbances provided by M*. For example, a magnetic bearing controller can be contemplated that acts differently on the rotating part and on the external disturbances.

In one embodiment, the mask M, and by extension the filtering template P, is defined relative to a predefined threshold of a characterisation indicator, for example, a predefined threshold of a polarisation rate, and/or of a circularity indicator of an equivalent ellipse as described above.

The constancy of a characterisation indicator also can be used to define a filtering template relative to said characterisation indicator.

Finally, a step 140 is carried out of applying the filtering template P to the signal to be filtered, for example, a signal determined based on measurements representing the movement of the rotating shaft.

In one embodiment, the filtering template is applied to the time-frequency decomposition of the bivariate signal so as to obtain a filtered bivariate signal R and its jointly computed dual R*. Step 140 is then carried out according to various embodiments.

Starting from the time-frequency decomposition using a short-term single-sided Fourier transform, a step 141 is obtained of computing an intermediate filtered bivariate signal \grave{R}, its dual \grave{R}*, and components of the filtered input signals determined in step 20 Ùₓ, Ùₓ*, Ù_{y}*, and Ù_{y}.

$$∀ t ∈ {T}_{↓} ∀ τ ∈ [ t - {dt}^{-} , t + {dt}^{+} ] , \qquad \begin{matrix}{{U}^{′}}_{x} ( t , τ ) = 2. Re ( {\sum }_{f ∈ {F}_{+}} c ( f ) . P ( t , f ) . {\hat{s}}_{x} ( t , f ) . {e}^{1 i \text{.2} π . f . τ} ) \\ {{U}^{′}}_{y} ( t , τ ) = 2. Re ( {\sum }_{f ∈ {F}_{+}} c ( f ) . P ( t , f ) . {\hat{s}}_{y} ( t , f ) . {e}^{1 i \text{.2} π . f . τ} ) \\ {{U}_{x}^{*}}^{′} ( t , τ ) = 2. Re ( {\sum }_{f ∈ {F}_{+}} c ( f ) . {P}^{*} ( t , f ) . {\hat{s}}_{x} ( t , f ) . {e}^{1 i \text{.2} π . f . τ} ) \\ {{U}_{y}^{*}}^{′} ( t , τ ) = 2. Re ( {\sum }_{f ∈ {F}_{+}} c ( f ) . {P}^{*} ( t , f ) . {\hat{s}}_{y} ( t , f ) . {e}^{1 i \text{.2} π . f . τ} )\end{matrix}$$

$$avec : \qquad \begin{matrix}c ( 0 ) = 0.5 \\ \begin{matrix}∀ f \neq 0 , & c ( f ) = 1\end{matrix}\end{matrix}$$

$$and$$

$$∀ t ∈ {T}_{↓} ∀ τ ∈ [ t - {dt}^{-} , t + {dt}^{+} ] , \qquad \begin{matrix}{R}^{′} ( t , τ ) = {{U}^{′}}_{x} ( t , τ ) + 1 i . {{U}^{′}}_{y} ( t , τ ) \\ {{R}^{*}}^{′} ( t , τ ) = {{U}_{x}^{*}}^{′} ( t , τ ) + 1 i . {{U}_{y}^{*}}^{′} ( t , τ )\end{matrix}$$

Starting from the time-frequency decomposition using a short-term two-sided Fourier transform, a step 142 of computing the intermediate filtered bivariate signal \grave{R}, its dual \grave{R}*, is obtained such that:

$$∀ t ∈ {T}_{↓} ∀ τ ∈ [ t - {dt}^{-} , t + {dt}^{+} ] , \qquad \begin{matrix}{R}^{′} ( t , τ ) = P ( t , 0 ) . \tilde{s} ( t , 0 ) + {\sum }_{f ∈ {F}_{+}^{*}} ( P ( t , f ) . \tilde{s} ( t , f ) . {e}^{1 i \text{.2} π . f . τ} + P ( t , f ) . \tilde{s} ( t , f ) . {e}^{- 1 i \text{.2} π . f . τ} ) \\ {{R}^{*}}^{′} ( t , τ ) = {P}^{*} ( t , 0 ) . \tilde{s} ( t , 0 ) + {\sum }_{f ∈ {F}_{+}^{*}} ( {P}^{*} ( t , f ) . \tilde{s} ( t , f ) . {e}^{1 i \text{.2} π . f . τ} + {P}^{*} ( t , f ) . \tilde{s} ( t , f ) . {e}^{- 1 i \text{.2} π . f . τ} )\end{matrix}$$

Starting from the time-frequency decomposition using a short-term quaternionic Fourier transform, a step 143 of computing the intermediate filtered bivariate signal \grave{R}, its dual \grave{R}*, is obtained such that:

$$∀ t ∈ {T}_{↓} ∀ τ ∈ [ t - {dt}^{-} , t + {dt}^{+} ] , \qquad \begin{matrix}{R}^{′} ( t , τ ) = {Proj}_{{C}_{1 i}} ( {\sum }_{f ∈ {F}_{+}} P ( t , f ) . {s}^{o} ( t , f ) . {e}^{1 i \text{.2} π . f . τ} ) \\ {{R}^{′}}^{*} ( t , τ ) = {Proj}_{{C}_{1 i}} ( {\sum }_{f ∈ {F}_{+}} {P}^{*} ( t , f ) . {s}^{o} ( t , f ) . {e}^{1 i \text{.2} π . f . τ} )\end{matrix}$$

Finally, the following equality 144 can be used to determine the filtered bivariate signal R and its dual R* by reconstructing the complete time axis as parts:

$$∀ t ∈ {T}_{↓} \begin{matrix}{R}^{′} ( [ t - {dt}^{-} , t + {dt}^{+} ] ) = R ( t , [ t - {dt}^{-} , t + {dt}^{+} ] ) \\ {R}^{*} ( [ t - {dt}^{-} , t + {dt}^{+} ] ) = {{R}^{*}}^{′} ( t , [ t - {dt}^{-} , t + {dt}^{+} ] )\end{matrix}$$

Optionally, a step 150 is carried out of obtaining filtered input signals U₁ to U_{M}, by projecting the filtered bivariate signal R onto the axes collinear with the measured quantities.

The filtering template allows specific frequency ranges to be selected from the input signals.

In a particular embodiment, several filtering templates are applied successively and/or in combination. In addition, the filtering method can be applied to measurements carried out in different planes or for different quantities.

In a particular embodiment, all the steps of the method are computer-implemented, with the possibility of real time execution, notably in a magnetic bearing control cabinet.

Some terms and functions used in the computations described above are redefined below:

The set of strictly positive frequencies is: F₊*={fⱼ, j=[1, n]}

The set of strictly negative frequencies is: F₋*=−F₊

The following is also defined: F₊={0}∪F₊*

The following is also defined: F₋=F*∪{0}

The complete set of frequencies is: F=F₋∪F₊=F₋*∪{0}∪F₊*

The generic stationarity function is:

$$∀ t ∈ TT , \qquad \begin{matrix}pour tol > 0 : autostat ( x ( t ) , tol ) = {e}^{- \frac{\vert dx ( t ) \vert}{tol}} \\ pour tol = 0 : autostat ( x ( t ) , 0 ) = ( dx ( t ) == 0 )\end{matrix}$$

The maximum function with exception is:

$${max}^{*} ( x ) = \begin{matrix}max ( x ) si max ( x ) \neq 0 \\ 1 sinon\end{matrix}$$

The normalisation function is:

$$∀ t ∈ TT , ∀ f ∈ FF , {normalise}_{τ ∈ TT , v ∈ FF} ( x ( t , f ) ) = \frac{x ( t , f )}{{max}_{τ ∈ TT , v ∈ FF}^{*} ( \vert x ( τ , v ) \vert )}$$

The division function with exception is:

$${ratio}^{*} ( x , y ) = \begin{matrix}x / y si y \neq 0 \\ 0 sinon\end{matrix}$$

The relative error function is:

$$reldif ( x , y ) = {ratio}^{*} ( 2. \vert x - y \vert , \vert x \vert + \vert y \vert )$$

The definition of the arctan 2 function is also provided by way of a reminder, with a formulation equivalent to the argument of the complex number x+1μ. y:

$$Arg ( x + 1 μ . y ) = arctan 2 ( y , x )$$

What is claimed is:

1. A method for filtering at least one signal to be filtered, with the filtering being determined based on measurements representing the movement of a rotating shaft, the method comprising:
defining at least one characterisation indicator of the rotating shaft, with the characterisation indicator being obtained from a frequency analysis of the behaviour of the rotating shaft;
determining a filtering template as a function of the characterisation indicator; and
applying the filtering template to said signal to be filtered.

2. The method according to claim 1, wherein the characterisation indicator is obtained from the following steps:
acquiring at least two input signals over a predetermined period, the input signals comprising measurements representing the movement of the rotating shaft, the measurements being non-collinear to each other;
determining two components of the input signals, the components being orthogonal to each other;
merging the two components into a bivariate signal;
time-frequency decomposing the bivariate signal into spectral elements;
determining an equivalent ellipse for each spectral element; and
extracting the characterisation indicator of the rotating shaft based on parameters of the equivalent ellipse.

3. The method according to claim 2, wherein the filtering template is applied to the time-frequency decomposition of the bivariate signal so as to obtain a filtered bivariate signal.

4. The method according to claim 3, wherein the time-frequency decomposition of the bivariate signal on which the filtering template is applied is a time-frequency decomposition that is obtained using a Fourier, or wavelet, transform, or by filtering, or using a quaternionic Fourier transform.

5. The method according to claim 3, further comprising a step of obtaining filtered input signals by projecting the filtered bivariate signal onto the axes collinear with the measured quantities.

6. The method according to claim 3, further comprising a step of computing a dual signal of the filtered bivariate signal.

7. The method according to claim 2, wherein the at least one indicator includes a polarisation rate, and/or an indicator of circularity and/or amplitude and/or direction and/or orientation and/or synchronisation of an equivalent ellipse.

8. The method according to claim 2, wherein the filtering template is defined relative to a predefined threshold of a polarisation rate, and/or a circularity indicator of an equivalent ellipse.

9. The method according to claim 1, wherein the filtering template is defined based on at least one normalised indicator ranging between −1 and 1 or between 0 and 1.

10. The method according to claim 1, wherein the filtering template is a linear bivariate filter and/or is obtained by multiplying a mask that is determined as a function of the characterisation indicator and of a frequency weighting.

11. The method according to claim 4, further comprising a step of obtaining filtered input signals by projecting the filtered bivariate signal onto the axes collinear with the measured quantities.

12. The method according to claim 11, further comprising a step of computing a dual signal of the filtered bivariate signal.

13. The method according to claim 12, wherein the at least one indicator includes a polarisation rate, and/or an indicator of circularity and/or amplitude and/or direction and/or orientation and/or synchronisation of an equivalent ellipse.

14. The method according to claim 13, wherein the filtering template is defined relative to a predefined threshold of a polarisation rate, and/or a circularity indicator of an equivalent ellipse.

15. The method according to claim 14, wherein the filtering template is defined based on at least one normalised indicator ranging between −1 and 1 or between 0 and 1.

16. The method according to claim 15, wherein the filtering template is a linear bivariate filter and/or is obtained by multiplying a mask that is determined as a function of the characterisation indicator and of a frequency weighting.
